(19) United States
(12) Patent Application Publication
(10) Pub. No.: US 2026/0271769 A1
(43) Pub. Date: Sep. 10, 2026

(54) SEMICONDUCTOR DEVICE

(71) Applicant: Mitsubishi Electric Corporation, Tokyo (JP)

(72) Inventor: Kazuya OKADA, Tokyo (JP)

(73) Assignee: Mitsubishi Electric Corporation, Tokyo (JP)

(21) Appl. No.: 19/435,450

(22) Filed: Dec. 29, 2025

(30) Foreign Application Priority Data
Mar. 5, 2025 (JP) 2025-034450

(51) Int. Cl. H10W 72/90; H10W 90/00

(52) U.S. Cl. CPC H10W 72/932; H10W 90/754

(57) ABSTRACT

An object is to provide a technique capable of reducing a difference of potential between a gate and a source in each area sectioned by a gate line in a semiconductor device. In the semiconductor device, a source pad is sectioned into two pieces by an inner gate line. Each of the source wires connects each source pad sectioned by the inner gate line to a source pattern. When a length of a side perpendicular to the inner gate line in each of areas is K, and each K in the areas is defined as Ka and Kb in descending order, parasitic inductances La and Lb of the source wires connecting the source pad of the areas corresponding to Ka and Kb, respectively, satisfy a relationship of La<Lb.

### BACKGROUND

### Technical Field

The present disclosure relates to a semiconductor device.

### Description of the Background Art

Japanese Patent Application Laid-Open No. 2005-261035 describes a technique of adjusting the number of bonding wires connected to semiconductor elements to suppress ununiform and excess peak current of gate-source voltage between the plurality of semiconductor elements in switching of a semiconductor device.

In the technique described in Japanese Patent Application Laid-Open No. 2005-261035, impedance of the bonding wire is adjusted by changing a length or the number of the bonding wires on the semiconductor element to reduce a difference of the gate-source voltage between the plurality of semiconductor elements. Accordingly, excess peak current in a specific semiconductor element and an oscillation phenomenon between a plurality of semiconductor elements are suppressed.

### SUMMARY

However, the technique described in Japanese Patent Application Laid-Open No. 2005-261035 has a problem that in a semiconductor element having a cell structure in which cells are parallelly connected and sectioned by a gate line, a difference of potential between a gate and a source in each area sectioned by the gate line cannot be reduced.

An object of the present disclosure is to provide a technique capable of reducing a difference of potential between a gate and a source in each area sectioned by a gate line in a semiconductor device.

A semiconductor device according to the present disclosure includes an insulating substrate and a semiconductor element. A drain pattern and a source pattern are provided to the insulating substrate. The semiconductor element is disposed on the drain pattern of the insulating substrate. The semiconductor element includes a gate pad, a source pad, an outer surrounding gate line, an inner gate line, and two areas. The outer surrounding gate line is connected to the gate pad and provided along an outer surrounding on the semiconductor element. The inner gate line is connected to two sides facing each other in the outer surrounding gate line. The two areas are sectioned by the inner gate line, and has a cell structure that each of the two areas is parallelly connected. The source pad is sectioned into two pieces by the inner gate line. Each the source pad sectioned by the inner gate line and the source pattern are connected by each source wire. When a length of a side perpendicular to the inner gate line in each of the areas is K, and each the K in each of the areas is defined as Ka and Kb in descending order, parasitic inductances La and Lb of the each source wire connecting each the source pad of the areas corresponding to Ka and Kb satisfy a relationship of La<Lb.

A difference of potential between a gate and a source in each area sectioned by the inner gate line can be reduced.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematical view of an upper surface structure of a semiconductor device according to an embodiment 1.

FIG. 2 is a schematical view of gate-source potential in FIG. 1.

FIG. 3 is a schematical view of an upper surface of a semiconductor device in a case where non-uniformity occurs in gate-source voltage.

FIG. 4 is a schematical view of gate-source potential in FIG. 3.

FIG. 5 is a schematical view of an upper surface structure of a semiconductor device according to an embodiment 2.

FIG. 6 is a schematical view of gate-source potential in FIG. 5.

FIG. 7 is a schematical view of an upper surface structure of a semiconductor device according to an embodiment 3.

FIG. 8 is a schematical view of an upper surface structure of a semiconductor device according to an embodiment 4.

### DESCRIPTION OF THE PREFERRED EMBODIMENTS

### Embodiment 1

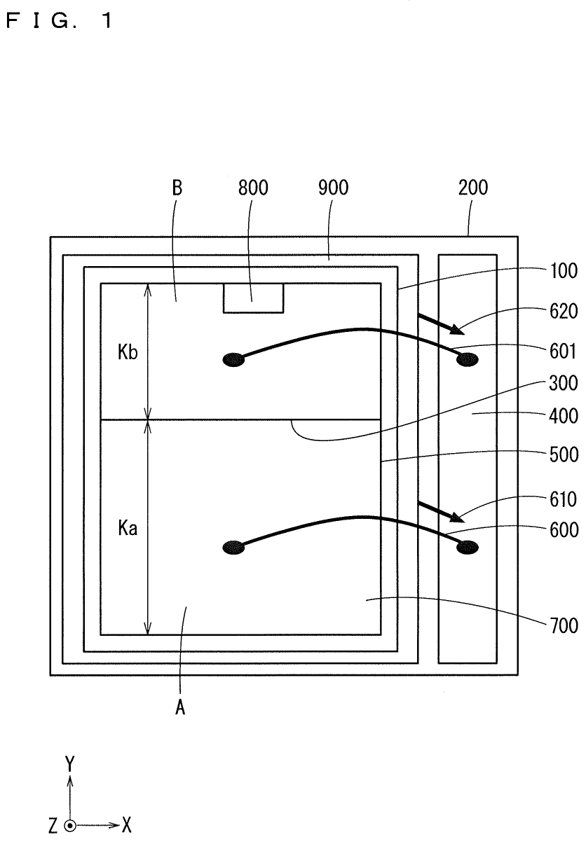

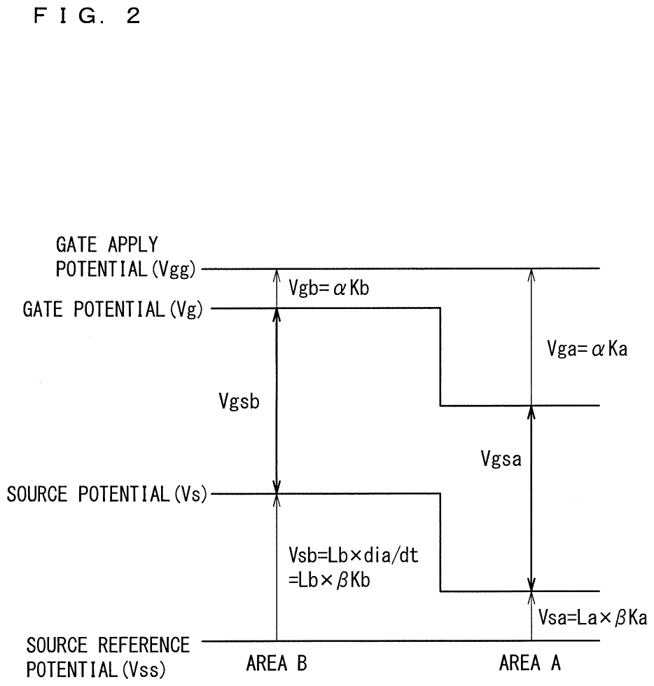

An embodiment 1 is described hereinafter using the diagrams. FIG. 1 is a schematical view of an upper surface structure of a semiconductor device according to the embodiment 1. FIG. 2 is a schematical view of gate-source potential in FIG. 1.

In FIG. 1, an X direction, a Y direction, and a Z direction are perpendicular to each other. An X direction, a Y direction, and a Z direction illustrated in the subsequent diagrams are also perpendicular to each other. In the description hereinafter, a direction including the X direction and a −X direction as a direction opposite to the X direction is also referred to as “an X axis direction”. In the description hereinafter, a direction including the Y direction and a −Y direction as a direction opposite to the Y direction is also referred to as “a Y axis direction”. In the description hereinafter, a direction including the Z direction and a −Z direction as a direction opposite to the Z direction is also referred to as “a Z axis direction”.

As illustrated in FIG. 1, the semiconductor device is a power semiconductor device, and includes an insulating substrate 200 and a semiconductor element 100.

The insulating substrate 200 is formed into a quadrangular shape in a top view (seen from a Z direction). The insulating substrate 200 includes an insulating layer made of ceramics or epoxy resin, for example. Ceramics is aluminum oxide, aluminum nitride, or silicon nitride, for example. A drain pattern 900 and a source pattern 400 are provided at an interval in an X axis direction on an upper surface (a surface in the Z direction) of the insulating substrate 200.

The semiconductor element 100 is disposed on the drain pattern 900 (the Z direction) of the insulating substrate 200. The semiconductor element 100 includes a gate pad 800, a source pad 700, an outer surrounding gate line 500, an inner gate line 300, and two areas A and B.

The gate pad 800 is provided in a center part of the semiconductor element 100 in an X direction and an end part thereof in a Y direction in a top view (seen from the Z direction). The source pad 700 is provided in a region except for the gate pad 800 in the semiconductor element 100 in a top view (seen from the Z direction). The outer surrounding gate line 500 is provided along a peripheral edge part of the semiconductor element 100 in a top view (seen from the Z direction).

The inner gate line 300 extends in the X axis direction, and is connected to two sides facing each other and extending in a Y axis direction in the outer surrounding gate line 500. Two areas A and B are areas of the source pad 700 sectioned by the inner gate line 300, and have a cell structure that the each of the areas A and B is parallelly connected.

Two areas A and B sectioned by the inner gate line 300 are connected to the source pattern 400 via source wires 600 and 601, respectively. A distance from the source pattern 400 to each of the areas A and B is the same as each other.

Adoptable as a material constituting the semiconductor element 100 is silicon carbide (SiC) as a wide bandgap semiconductor in addition to silicon (Si), for example. An Si semiconductor element or an SiC semiconductor element using silicon (Si) or silicon carbide (SiC) as a substrate material is adopted as the semiconductor element 100. Examples of a wide bandgap semiconductor include gallium nitride (GaN) series material or diamond. When the wide bandgap semiconductor is adopted as a material constituting the semiconductor element 100, the semiconductor device can be downsized by reason that the wide bandgap semiconductor has a high allowable current density and low electrical power loss.

Adopted as the semiconductor element 100, for example, is a metal oxide semiconductor field effect transistor (MOSFET) controlling large current, a power control semiconductor element (switching element) such as an insulated gate bipolar transistor (IGBT), or a reflux diode.

Next, a feature of the semiconductor device according to the embodiment 1 is described using FIG. 1 and FIG. 2. As illustrated in FIG. 1, a length of a side (a side extending in the Y axis direction) perpendicular to the inner gate line 300 in each of the areas A and B is K, and the K in each of the areas A and B is defined as Ka and Kb in descending order. That is to say, since the area A has the larger K than the area B, the K of the area A is defined as Ka, and the K of the area B is defined as Kb. Parasitic inductances La and Lb of each of the source wires 600 and 601 connecting the source pad 700 in each of the areas A and B corresponding to Ka and Kb, respectively, satisfy a relationship of La<Lb. That is to say, each of the source wires 600 and 601 is disposed to satisfy the relationship of La<Lb.

Known is a problem that when gate-source voltage of the semiconductor element is non-uniform in a high-speed operation of the semiconductor device, a current concentration to a specific semiconductor element or an oscillation phenomenon occurs. Known is a method of routing the inner gate line in a surface of a semiconductor element for a purpose of uniforming gate potential. However, non-uniformity of source potential occurs between source pads sectioned by the inner gate line. Thus, uniformity of gate-source voltage is blocked.

In the semiconductor device according to the embodiment 1, when gate-source current associated with a switching operation flows from the gate pad 800 to the source wires 600 and 601, a cell located in a center of each of the areas A and B among parallel-connected cells in the areas A and B has a largest distance from a gate line such as the outer surrounding gate line 500 or the inner gate line 300. Thus, largest voltage drop of gate potential occurs in the cell located in the center of each of the areas A and B. As illustrated in FIG. 2, magnitudes Vga and Vgb of this voltage drop are determined by Ka and Kb, thus can be expressed as Vga=αKa and Vgb=αKb when α is a coefficient, and Vga>Vgb is satisfied.

In the similar manner, when gate-source current associated with a switching operation flows from the gate pad 800 to the source wires 600 and 601, Vsa=La×dia/dt and Vsb=Lb×dib/dt are satisfied by reason that induced electromotive force generated in the source wires 600 and 601 is equal to a product of a self-inductance L of the source wires 600 and 601 and a time variation di/dt of current flowing in the source wires 600 and 601. Arrows 610 and 620 in FIG. 1 indicate magnitudes of amounts dia/dt and dib/dt of current flowing into the source wires 600 and 601, respectively.

The amounts dia/dt and dib/dt of current flowing into the source wires 600 and 601, respectively, are proportional to an area as amounts of cells included in the area A and B, respectively, thus can be expressed as dia/dt=βKa and dib/dt=βKb when β is a coefficient. Accordingly, Vsa=La×dia/dt=La×βKa and Vsb=Lb×dib/dt=Lb×βKb are satisfied.

Thus, the gate-source voltage Vgsa of the area A is expressed as:
Vgsa=Vgg−(αKa)−(La×βKa)−Vss

In order to uniform each gate-source voltage,
Vgsa=Vgsb is satisfied.
When Lb is described based on La,
Vgg−(αKa)−(La×βKa)−Vss=Vgg−(αKb)−(Lb×βKb)−Vss
(αKa)+(La×βKa)=(αKb)+(Lb×βKb)
(Lb×βKb)=(αKa)+(La×βKa)−(αKb) and
Lb=(α/β)×(Ka−Kb)/Kb+(Ka/Kb)×La are satisfied.

Since Ka>Kb is satisfied, Vgs of each of the areas A and B can be uniformed when Lb>La is satisfied.

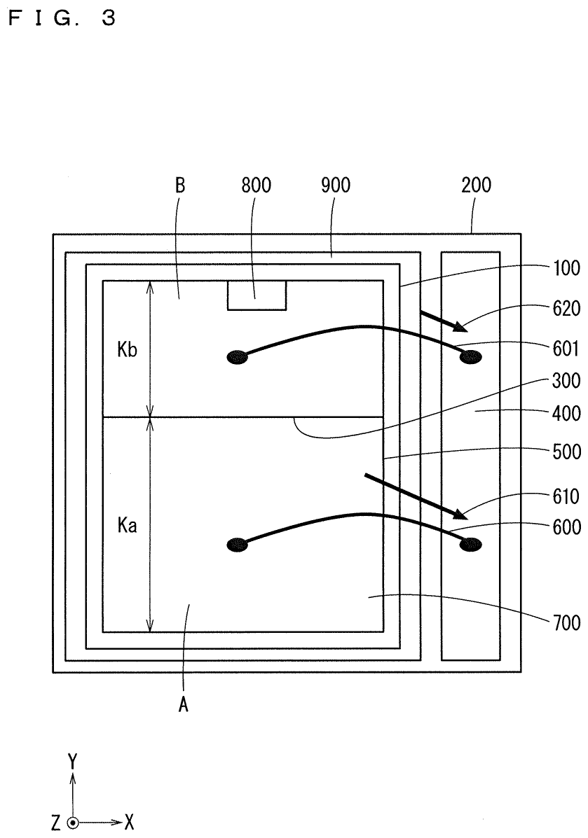

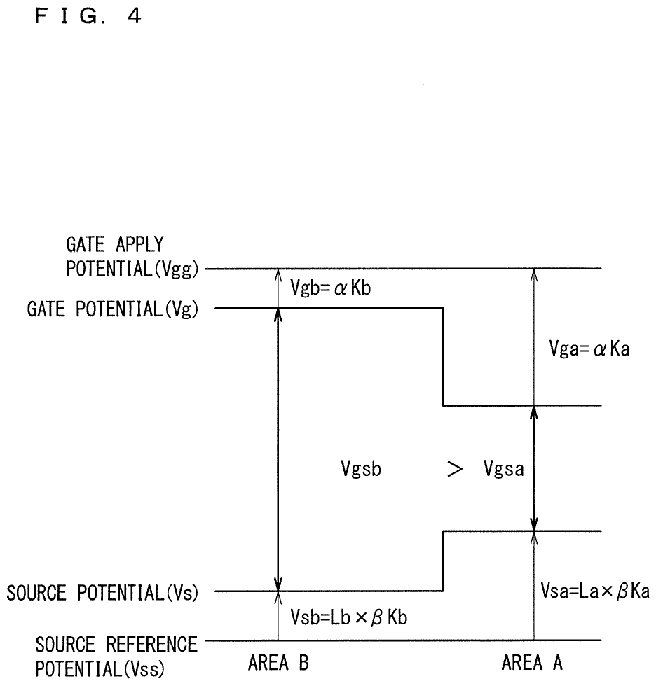

Described next is a case where non-uniformity occurs in the gate-source voltage Vgsa using FIG. 3 and FIG. 4. FIG. 3 is a schematical view of the upper surface of the semiconductor device in the case where non-uniformity occurs in the gate-source potential Vgsa. FIG. 4 is a schematical view of gate-source potential in FIG. 3.

As illustrated in FIG. 3, when the gate-source current associated with the switching operation flows from the gate pad 800 to the source wires 600 and 601, the cells located in the centers of the areas A and B among the cells included in the areas A and B, respectively, have the largest distance from the gate line such as the outer surrounding gate line 500 or the inner gate line 300. Thus, largest voltage drop of gate potential occurs in the cells located in the centers of the areas A and B, respectively.

As illustrated in FIG. 4, magnitudes Vga and Vgb of this voltage drop can be expressed as Vga=αKa and Vgb=αKb, and Vga>Vgb is satisfied.

In the meanwhile, when gate-source current associated with the switching operation flows from the gate pad 800 to the source wires 600 and 601, Vsa=La×dia/dt=La×βKa and Vsb=Lb×dib/dt=Lb×βKb are satisfied by reason that induced electromotive force generated in the source wires 600 and 601 is equal to a product of a self-inductance L of the source wires 600 and 601 and the time variation di/dt of current flowing in the source wires 600 and 601. Since La=Lb is satisfied in FIG. 3, Vsa>Vsb is satisfied in accordance with a relationship of Ka>Kb.

Thus, Vgsa<Vgsb is established as illustrated in FIG. 4, and Vgs cannot be uniformed in each of the areas A and B.

As the technique described in Japanese Patent Application Laid-Open No. 2005-261035, there is an example of a power semiconductor module in which impedance of the bonding wire is adjusted by making a change in the length or the number of the bonding wires on the semiconductor element in accordance with mutual inductance between the plurality of mounted semiconductor elements and a bus bar so that the difference of the gate-source voltage between the plurality of semiconductor elements can be reduced.

However, when the difference of the gate-source voltage between the areas is reduced in the semiconductor element including the areas including the cells sectioned by the inner gate line, impedance of the bonding wire corresponding to the mutual inductance between the semiconductor element and the bus bar cannot be adjusted. Thus, a problem of occurrence of excess peak current in a specific area is not considered.

In contrast, in the embodiment 1, the semiconductor device includes the insulating substrate 200 in which the drain pattern 900 and the source pattern 400 are provided and the semiconductor element 100 disposed on the drain pattern 900 of the insulating substrate 200. The semiconductor element 100 includes the gate pad 800, the source pad 700, the outer surrounding gate line 500 connected to the gate pad 800 and provided along the outer surrounding on the semiconductor element 100, the inner gate line 300 connected to two sides facing each other in the outer surrounding gate line 500, and two areas A and B sectioned by the inner gate line 300 and has the cell structure that each of the areas A and B is parallelly connected. The source pad 700 is sectioned into two pieces by the inner gate line 300. Each of the source wires 600 and 601 connects each source pad 700 sectioned by the inner gate line 300 to the source pattern 400. When the length of the side perpendicular to the inner gate line 300 in each of the areas A and B is K, and each K in the areas A and B is defined as Ka and Kb in descending order, parasitic inductances La and Lb of the source wires 600 and 601 connecting the source pad 700 of the areas A and B corresponding to Ka and Kb, respectively, satisfy the relationship of La<Lb.

Accordingly, a difference of potential between a gate and a source in each of the areas A and B sectioned by the inner gate line 300 can be reduced.

The parasitic inductances La and Lb of each source wire satisfy the relationship of
Lb=(α/β)×(Ka−Kb)/Kb+(Ka/Kb)×La

Accordingly, Lb can be determined to maximize the effect of uniforming Vgs in each of the areas A and B for a specific La in the parasitic inductance La of the source wire 600, for example. As a result, a difference of potential between the gate and the source in each of the areas A and B sectioned by the inner gate line 300 can be further reduced.

Described in FIG. 1 is the example that two areas A and B are provided to one semiconductor element as a minimum configuration. However, the configuration is not limited thereto, but the number of the semiconductor elements may be two or more.

When an area of each of the areas A and B are equal to each other and Ka=Kb is satisfied, the difference of the gate-source voltage between the areas A and B can be reduced by satisfying La=Lb.

### Embodiment 2

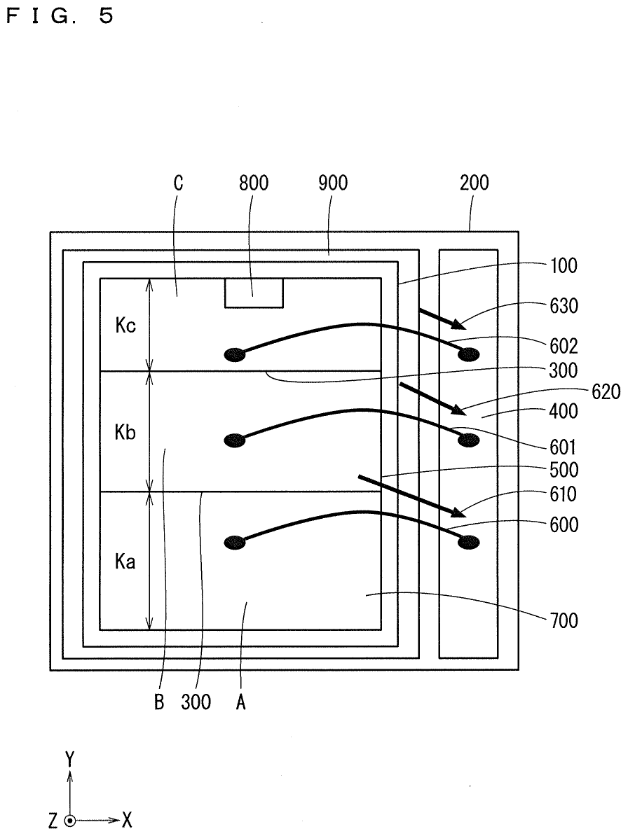

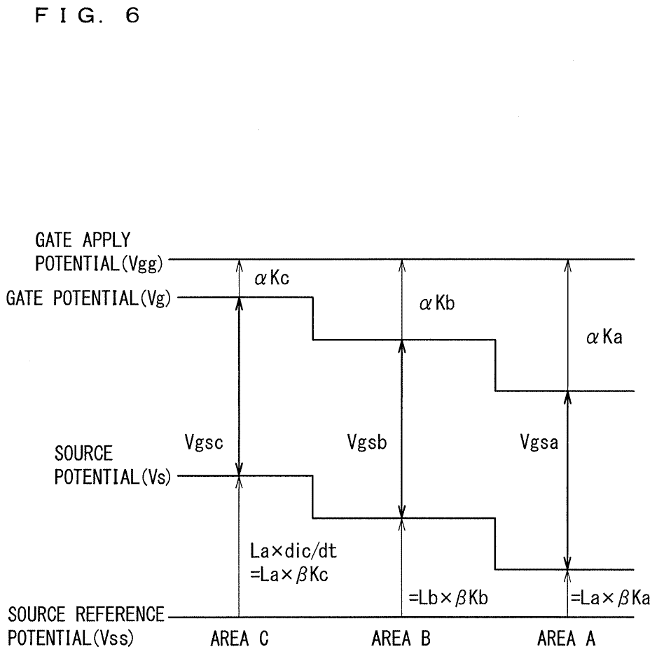

An embodiment 2 is described next. FIG. 5 is a schematic view of an upper surface structure of a semiconductor device according to the embodiment 2. FIG. 6 is a schematical view of gate-source potential in FIG. 5. In the description in the embodiment 2, the same reference numerals are assigned to the same constituent elements as those described in the embodiment 1, and the description thereof will be omitted.

As illustrated in FIG. 5, the embodiment 2 is different from the embodiment 1 in that the semiconductor element 100 includes three areas A, B, and C sectioned by two inner gate lines 300.

Both two inner gate lines 300 extend in the X axis direction, and are connected to two sides facing each other and extending in the Y axis direction in the outer surrounding gate line 500. Two inner gate lines 300 are provided at an interval in the Y axis direction. Three areas A, B, and C are areas of the source pad 700 sectioned by two inner gate lines 300, and have a cell structure that each of the areas A, B, and C is parallelly connected.

Three areas A, B, and C sectioned by two inner gate lines 300 are connected to the source pattern 400 via source wires 600, 601, and 602, respectively. A distance from the source pattern 400 to each of the areas A, B, and C is the same as each other.

K of each of the areas A, B, and C is defined as Ka, Kb, and Kc in descending order. That is to say, Ks of the areas A, B, and C are defined as Ka, Kb, and Kc, respectively. The parasitic inductances La, Lb, and Lc of the source wires 600, 601, and 602 connecting the source pad 700 of the areas A, B, and C corresponding to Ka, Kb, and Kc, respectively, satisfy a relationship of La<Lb<Lc. That is to say, each of the source wires 600, 601, and 602 is disposed to satisfy the relationship of La<Lb<Lc. According to this configuration, as illustrated in FIG. 6, the gate-source voltage can be uniformed in each of the areas A, B, and C. Arrows 610, 620, and 630 in FIG. 5 indicate magnitudes of amounts dia/dt, dib/dt, and dic/dt of current flowing into the source wires 600, 601, and 602, respectively.

In order to uniform each gate-source voltage,
Vgsa=Vgsb=Vgsc is satisfied.

(αKa)+(La×βKa)=(αKb)+(Lb×βKb)=(αKc)+(Lc×βKc) and
Lb=(α/β)×(Ka−Kb)/Kb+(Ka/Kb)×La are satisfied.
Since Ka>Kb is satisfied, Lb>La is satisfied.

Lc=(α/β)×(Kb−Kc)/Kc+(Kb/Kc)×Lb is satisfied.
Since Kb>Kc is satisfied, Lc>Lb is satisfied.

Thus, when Lc>Lb>La is satisfied, Vgs of each of the areas A, B, and C can be uniformed.

As described above, in the embodiment 2, included are the insulating substrate 200 in which the drain pattern 900 and the source pattern 400 are provided and the semiconductor element 100 disposed on the drain pattern 900 of the insulating substrate 200. The semiconductor element 100 includes the gate pad 800, the source pad 700, the outer surrounding gate line 500 connected to the gate pad 800 and provided along the outer surrounding on the semiconductor element 100, two inner gate lines 300 connected to two sides facing each other in the outer surrounding gate line 500, and three areas A, B, and C sectioned by two inner gate lines 300 and have the cell structure that each of the areas A, B, and C is parallelly connected. The source pad 700 is sectioned into three pieces by two inner gate lines 300. Each of the source wires 600, 601, and 602 connects each source pad 700 sectioned by two inner gate lines 300 to the source pattern 400. When the length of the side perpendicular to two inner gate lines 300 in each of the areas A, B, and C is K, and Ks in the areas A, B, and C are defined as Ka, Kb, and Kc in descending order, respectively, parasitic inductances La, Lb, and Lc of the source wires 600, 601, and 602 connecting the source pad 700 of the areas A, B, and C corresponding to Ka, Kb, and Kc, respectively, satisfy a relationship of La<Lb<Lc.

Accordingly, a difference of potential between a gate and a source in each of the areas A, B, and C sectioned by two inner gate lines 300 can be reduced.

The parasitic inductances La, Lb, and Lc of the source wires 600, 601, and 602, respectively, satisfy relationships of
Lb=(α/β)×(Ka−Kb)/Kb+(Ka/Kb)×La and
Lc=(α/β)×(Kb−Kc)/Kc+(Kb/Kc)×Lb

Accordingly, Lb and Lc can be determined to maximize the effect of uniforming Vgs in each of the areas A, B, and C for a specific La in the parasitic inductance La of the source wire 600, for example. As a result, a difference of potential between the gate and the source in each of the areas A, B, and C sectioned by the inner gate line 300 can be further reduced.

Described in FIG. 5 is the example that three areas A, B, and C are provided to one semiconductor element as a minimum configuration. However, the configuration is not limited thereto, but the number of the semiconductor elements may be two or more.

When an area of each of the areas A, B, and C is equal to each other and Ka=Kb Kc is satisfied, the difference of the gate-source voltage between the areas A, B, and C can be reduced by satisfying La=Lb=Lc.

### Embodiment 3

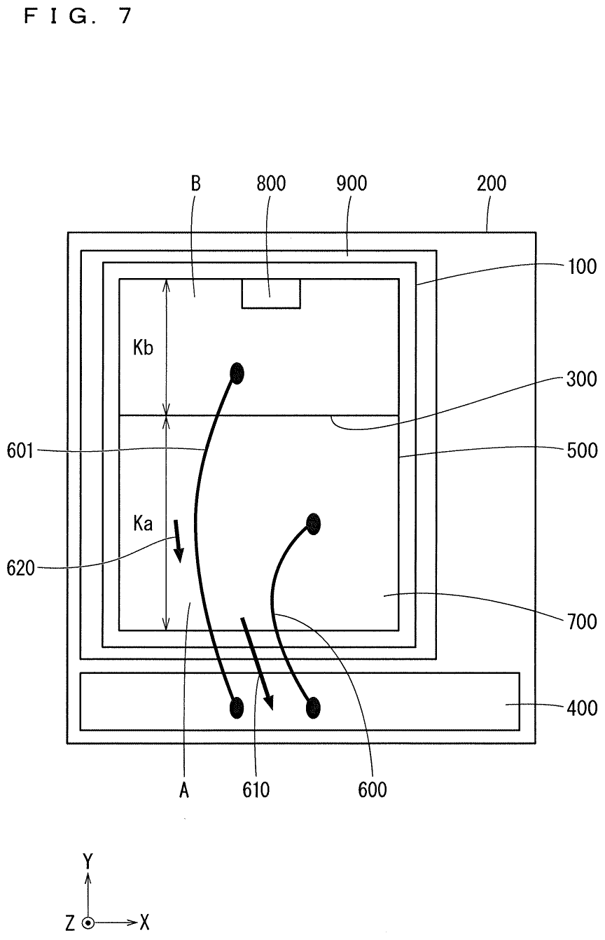

An embodiment 3 is described next. FIG. 7 is a schematic view of an upper surface structure of a semiconductor device according to the embodiment 3. In the description in the embodiment 3, the same reference numerals are assigned to the same constituent elements as those described in the embodiments 1 and 2, and the description thereof will be omitted.

As illustrated in FIG. 7, the embodiment 3 is different from the embodiment 1 in that the source pattern 400 is disposed closer to the area A corresponding to Ka than the area B corresponding to Kb. Specifically, the source pattern 400 is provided to an end part of the upper surface (the surface in the Z direction) in the −Y direction of the insulating substrate 200, and extends in the X axis direction. The drain pattern 900 is provided at an interval in the Y axis direction with the source pattern 400 on the upper surface (the surface in the Z direction) of the insulating substrate 200.

As described above, in the embodiment 3, the source pattern 400 is disposed closer to the area A corresponding to Ka than the area B corresponding to Kb.

Since a distance from the source pattern 400 to the area A is shorter than a distance from the source pattern 400 to the area B, the source wires 600 and 601 can be easily disposed so that the parasitic inductance La of the source wire 600 is smaller than the parasitic inductance Lb of the source wire 601, and the difference of the gate-source voltage of each of the areas A and B can be reduced.

The configuration according to the embodiment 3 can also be adopted to the embodiment 2. Although not shown, in this case, the source pattern 400 is disposed closer to the area A corresponding to Ka than the area B corresponding to Kb, and is disposed closer to the area B corresponding to Kb than the area C corresponding to Kc. Accordingly, the source wires 600, 601, and 602 can be easily disposed so that the parasitic inductances La, Lb, and Lc of the source wires 600, 601, and 602 satisfy the relationship of La<Lb<Lc, and the difference of the gate-source voltage of each of the areas A, B, and C can be reduced.

### Embodiment 4

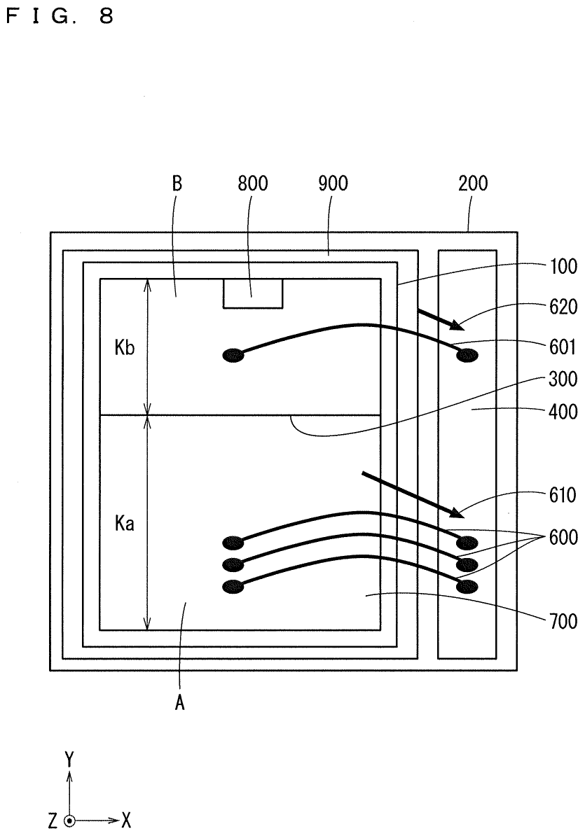

An embodiment 4 is described next. FIG. 8 is a schematic view of an upper surface structure of a semiconductor device according to the embodiment 4. In the description in the embodiment 4, the same reference numerals are assigned to the same constituent elements as those described in the embodiments 1 to 3, and the description thereof will be omitted.

As illustrated in FIG. 8, the embodiment 4 is different from the embodiment 1 in that the numbers Na and Nb of the source wires 600 and 601 satisfy a relationship of Na>Nb.

As described above, the number N of each of the source wires 600 and 601 is adjusted in the embodiment 4. Thus, the source wires 600 and 601 can be easily disposed so that the parasitic inductances of the source wires 600 and 601 satisfy Lb>La, and the difference of the gate-source voltage of each of the areas A and B can be reduced.

The configuration according to the embodiment 4 can also be adopted to the embodiment 2. Although not shown, in this case, the source wires 600, 601, and 602 are disposed so that the numbers Na, Nb, and Nc of the source wires 600, 601, and 602 satisfy the relationship of Na>Nb>Nc. Accordingly, the source wires 600, 601, and 602 can be easily disposed so that the parasitic inductances La, Lb, and Lc of the source wires 600, 601, and 602 satisfy the relationship of La<Lb<Lc, and the difference of the gate-source voltage of each of the areas A, B, and C can be reduced.

Each embodiment can be arbitrarily combined, or each embodiment can be appropriately varied or omitted.

The aspects of the present disclosure are collectively described hereinafter as appendixes.

### (Appendix 1)

A semiconductor device includes:
an insulating substrate in which a drain pattern and a source pattern are provided; and
a semiconductor element disposed on the drain pattern of the insulating substrate, wherein
the semiconductor element includes:
a gate pad and a source pad;
an outer surrounding gate line connected to the gate pad and provided along an outer surrounding on the semiconductor element;
an inner gate line connected to two sides facing each other in the outer surrounding gate line; and
two areas sectioned by the inner gate line and having a cell structure that each of the two areas is parallelly connected,
the source pad is sectioned into two pieces by the inner gate line,
each source wire connects each the source pad sectioned by the inner gate line to the source pattern, and
when a length of a side perpendicular to the inner gate line in each of the areas is K, and each the K in each of the areas is defined as Ka and Kb in descending order, parasitic inductances La and Lb of the each source wire connecting the source pad of each of the areas corresponding to Ka and Kb satisfy a relationship of La<Lb.

### (Appendix 2)

The semiconductor device according to Appendix 1, wherein
the parasitic inductances La and Lb of the each source wire satisfy a relationship of
Lb=(α/β)×(Ka−Kb)/Kb+(Ka/Kb)×La

### (Appendix 3)

A semiconductor device, comprising:
an insulating substrate in which a drain pattern and a source pattern are provided; and
a semiconductor element disposed on the drain pattern of the insulating substrate, wherein
the semiconductor element includes:
a gate pad and a source pad;
an outer surrounding gate line connected to the gate pad and provided along an outer surrounding on the semiconductor element;
two inner gate lines connected to two sides facing each other in the outer surrounding gate line; and
three areas sectioned by the two inner gate lines and having a cell structure that each of the three areas is parallelly connected,
the source pad is sectioned into three pieces by the two inner gate lines,
each source wire connects each the source pad sectioned by the two inner gate lines to the source pattern, and
when a length of a side perpendicular to the two inner gate lines in each of the areas is K, and each the K in each of the areas is defined as Ka, Kb, and Kc in descending order, parasitic inductances La, Lb, and Lc of the each source wire connecting the source pad of each of the areas corresponding to Ka, Kb, and Kc satisfy a relationship of La<Lb<Lc.

### (Appendix 4)

The semiconductor device according to Appendix 3, wherein
the parasitic inductances La, Lb, and Lc of the each source wire satisfy relationships of
Lb=(α/β)×(Ka−Kb)/Kb+(Ka/Kb)×La and
Lc=(α/β)×(Kb−Kc)/Kc+(Kb/Kc)×Lb

### (Appendix 5)

The semiconductor device according to Appendix 1, wherein
the source pattern is disposed closer to one of the areas corresponding to the Ka than another one of the areas corresponding to the Kb.

### (Appendix 6)

The semiconductor device according to Appendix 3, wherein
the source pattern is disposed closer to one of the areas corresponding to the Ka than another one of the areas corresponding to the Kb, and is disposed closer to the another one of the areas corresponding to the Kb than still another one of the areas corresponding to the Kc.

### (Appendix 7)

The semiconductor device according to Appendix 1, wherein
numbers Na and Nb of the each source wire satisfy a relationship of Na>Nb.

### (Appendix 8)

The semiconductor device according to Appendix 3, wherein
numbers Na, Nb, and Nc of the each source wire satisfy a relationship of Na>Nb>Nc.

While the disclosure has been shown and described in detail, the foregoing description is in all aspects illustrative and not restrictive. It is therefore understood that numerous modifications and variations can be devised.

What is claimed is:

1. A semiconductor device, comprising:
an insulating substrate in which a drain pattern and a source pattern are provided; and
a semiconductor element disposed on the drain pattern of the insulating substrate, wherein
the semiconductor element includes:
a gate pad and a source pad;
an outer surrounding gate line connected to the gate pad and provided along an outer surrounding on the semiconductor element;
an inner gate line connected to two sides facing each other in the outer surrounding gate line; and
two areas sectioned by the inner gate line and having a cell structure that each of the two areas is parallelly connected,
the source pad is sectioned into two pieces by the inner gate line,
each source wire connects each the source pad sectioned by the inner gate line to the source pattern, and
when a length of a side perpendicular to the inner gate line in each of the areas is K, and each the K in each of the areas is defined as Ka and Kb in descending order, parasitic inductances La and Lb of the each source wire connecting the source pad of each of the areas corresponding to Ka and Kb satisfy a relationship of La<Lb.

2. The semiconductor device according to claim 1, wherein
the parasitic inductances La and Lb of the each source wire satisfy a relationship of
Lb=(α/β)×(Ka−Kb)/Kb+(Ka/Kb)×La.

3. A semiconductor device, comprising:
an insulating substrate in which a drain pattern and a source pattern are provided; and
a semiconductor element disposed on the drain pattern of the insulating substrate, wherein
the semiconductor element includes:
a gate pad and a source pad;
an outer surrounding gate line connected to the gate pad and provided along an outer surrounding on the semiconductor element;
two inner gate lines connected to two sides facing each other in the outer surrounding gate line; and
three areas sectioned by the two inner gate lines and having a cell structure that each of the three areas is parallelly connected,
the source pad is sectioned into three pieces by the two inner gate lines,
each source wire connects each the source pad sectioned by the two inner gate lines to the source pattern, and
when a length of a side perpendicular to the two inner gate lines in each of the areas is K, and each the K in each of the areas is defined as Ka, Kb, and Kc in descending order, parasitic inductances La, Lb, and Lc of the each source wire connecting the source pad of each of the areas corresponding to Ka, Kb, and Kc satisfy a relationship of La<Lb<Lc.

4. The semiconductor device according to claim 3, wherein
the parasitic inductances La, Lb, and Lc of the each source wire satisfy relationships of
Lb=(α/β)×(Ka−Kb)/Kb+(Ka/Kb)×La and
Lc=(α/β)×(Kb−Kc)/Kc+(Kb/Kc)×Lb.

5. The semiconductor device according to claim 1, wherein
the source pattern is disposed closer to one of the areas corresponding to the Ka than another one of the areas corresponding to the Kb.

6. The semiconductor device according to claim 3, wherein
the source pattern is disposed closer to one of the areas corresponding to the Ka than another one of the areas corresponding to the Kb, and is disposed closer to the another one of the areas corresponding to the Kb than still another one of the areas corresponding to the Kc.

7. The semiconductor device according to claim 1, wherein
numbers Na and Nb of the each source wire satisfy a relationship of Na>Nb.

8. The semiconductor device according to claim 3, wherein
numbers Na, Nb, and Nc of the each source wire satisfy a relationship of Na>Nb>Nc.
